(19) United States
(12) Patent Application Publication
(10) Pub. No.: US 2026/0271804 A1
(43) Pub. Date: Sep. 10, 2026

(54) MEMORY SYSTEM WITH DIRECT CHIP ATTACH MEMORY DIE

(71) Applicant: Micron Technology, Inc., Boise, ID (US)

(72) Inventors: Anil Kumar Maganti, Hyderabad (IN); Pankaj Ramesh Chandra Katiyar, Hyderabad (IN)

(21) Appl. No.: 19/541,165

(22) Filed: Feb. 16, 2026

Related U.S. Application Data
(60) Provisional application No. 63/769,592, filed on Mar. 10, 2025.

(51) Int. Cl. H10W 90/00; H05K 1/02; H05K 1/03; H05K 1/181; H05K 3/341; H10B 80/00; H10W 40/20; H10W 72/00; H10W 72/20; H10W 90/20

(52) U.S. Cl. CPC H10W 90/724; H05K 1/0209; H05K 1/181; H05K 3/3426; H10B 80/00; H10W 40/235; H10W 72/07236; H10W 72/263; H10W 72/265; H10W 72/267; H10W 90/288; H05K 1/0306; H05K 1/032; H05K 2201/09472; H05K 2201/10159; H05K 2201/10734; H05K 2203/0338

(57) ABSTRACT

Methods, systems, and devices for memory system with direct chip attach memory die are described. A memory module may be formed using direct chip attach techniques that directly couple a memory die with a module substrate. By directly coupling the memory die with the module substrate, a semiconductor package including a package substrate that serves as an interface between the memory die and the module substrate may be eliminated.

### CROSS REFERENCE

The present Application for Patent claims priority to U.S. Patent Application No. 63/769,592 by Maganti et al., entitled “MEMORY SYSTEM WITH DIRECT CHIP ATTACH MEMORY DIE,” filed Mar. 10, 2025, which is assigned to the assignee hereof, and which is expressly incorporated by reference in its entirety herein.

### TECHNICAL FIELD

The following relates to one or more systems for memory, including a memory system with a direct chip attach memory die.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory system with a direct chip attach memory die in accordance with examples as disclosed herein.

FIG. 2 shows an example of a memory module of a memory system with a direct chip attach memory die in accordance with examples as disclosed herein.

FIG. 3 shows an example portion of a memory module of a memory system with a direct chip attach memory die in accordance with examples as disclosed herein.

FIGS. 4A and 4B show an example manufacturing process that supports a memory system with a direct chip attach memory die in accordance with examples as disclosed herein.

FIG. 5 shows a flowchart illustrating a method or methods that support a memory system with direct chip attach memory die in accordance with examples as disclosed herein.

### DETAILED DESCRIPTION

A memory module, such as a dual in line memory (DIMM) memory module that includes a dynamic random access memory (DRAM) device, may use a semiconductor package that encapsulates the DRAM device. The semiconductor package may be mounted to a module substrate (e.g., a printed circuit board (PCB)) and include a package substrate that serves as an interface between the DRAM device (e.g., a DRAM integrated circuit die) and the module substrate. In addition to consuming additional raw materials, use of the semiconductor package can increase signaling lengths in the memory module (e.g., the semiconductor package may include lengthy wire bonds, which may increase parasitics (e.g., inductance) and decrease the performance of the memory module). In some cases, portions of routing of traces and/or pads of the package substrate may be standardized to a joint electron device engineering committee (JEDEC) standard.

In accordance with examples as described herein, a memory module may be formed using direct chip attach (DCA) techniques that directly couple a memory die with a module substrate. By directly coupling the memory die with the module substrate, a semiconductor package including a package substrate that serves as an interface between the memory die and the module substrate may be eliminated. Eliminating the semiconductor package and/or the package substrate may reduce signaling lengths in the memory module and reduce parasitics in the memory module to improve the performance of the memory module (e.g., improve the signaling speed).

In addition to applicability in memory systems as described herein, techniques for forming a memory system with a direct chip attach memory die may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving data transfer between devices to enable increased communications between devices)], among other benefits.

Features of the disclosure are illustrated and described in the context of systems and architectures. Features of the disclosure are further illustrated and described in the context of a system including a memory module having a direct chip attach memory die, details of the memory module, processes to fabricate the memory module, and flowcharts.

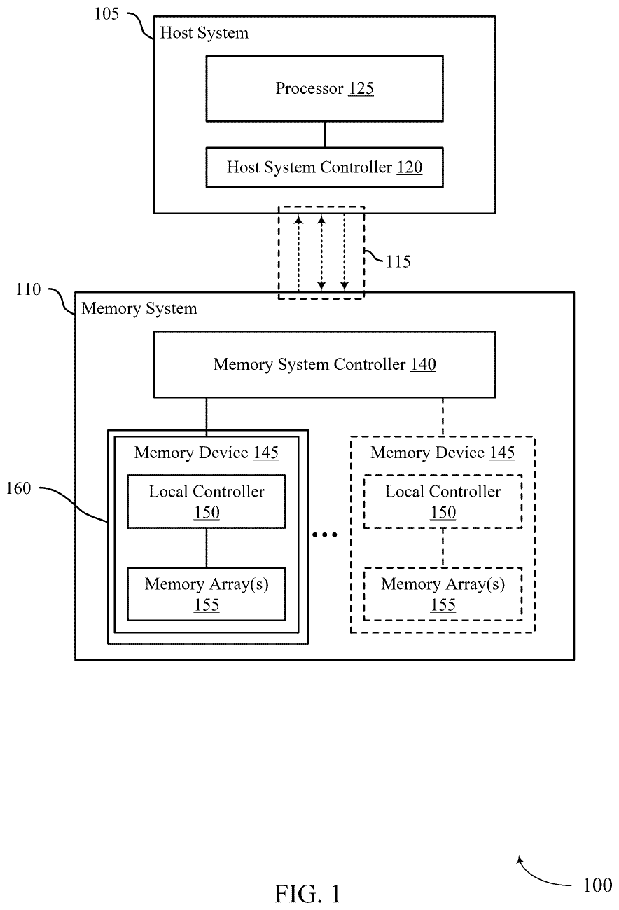

FIG. 1 shows an example of a system 100 that supports a memory system with direct chip attach memory die in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

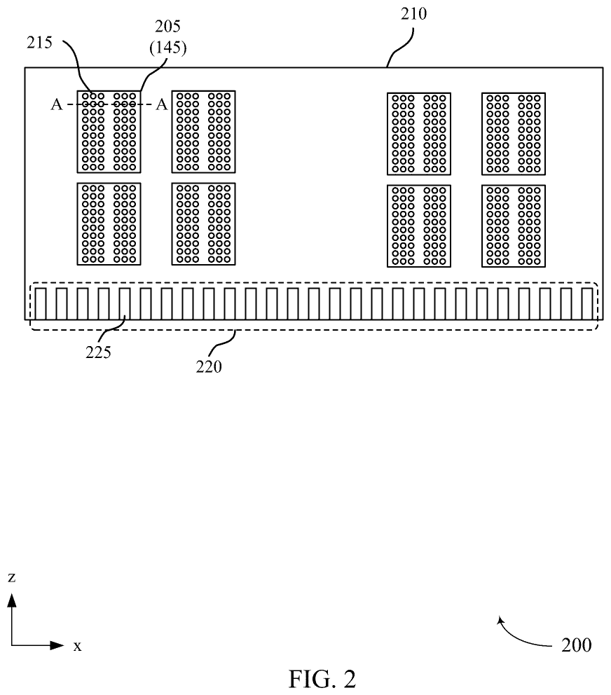

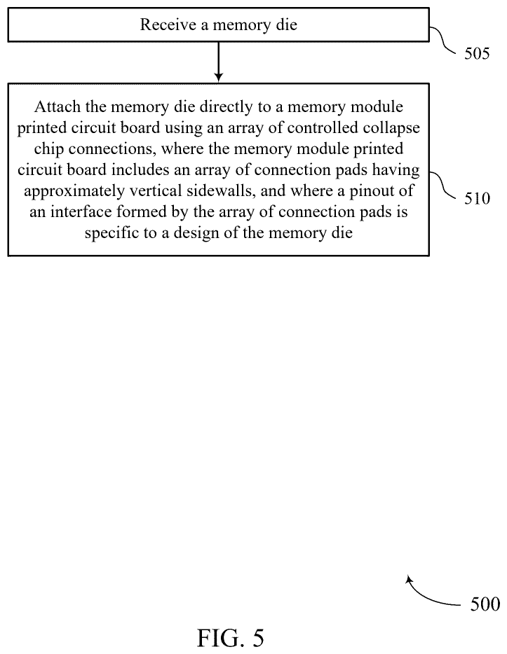

In some implementations, one or more features of the memory system 110 may be included as part of a memory module that is formed using direct chip attach (e.g., DCA) techniques. For example, and as described in greater detail in connection with FIGS. 2 through 5, each memory device 145 may be a memory integrated circuit die (e.g., a chip) that is coupled with a module substrate (e.g., a PCB) using direct chip attach techniques. For example, interface 160 between the memory device 145 and the memory system 110 may be formed using DCA techniques.

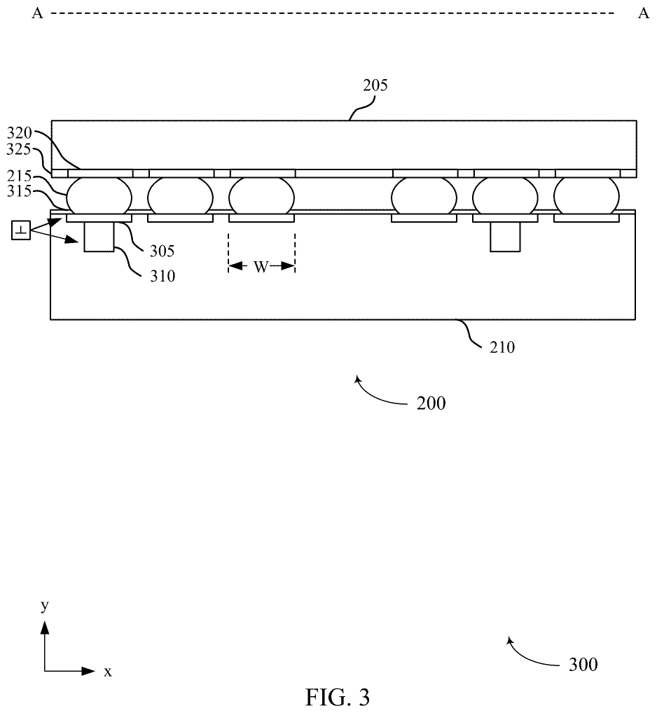

FIG. 2 shows an example of a memory module 200 of a memory system (e.g., the memory system 110 of FIG. 1) with a direct chip attach memory die in accordance with examples as disclosed herein. The view of the memory module 200 in FIG. 2 corresponds to an x-z plane and includes section A-A that is referenced in connection with FIGS. 3 through 5.

In some examples, the memory module 200 may be a dual-in line (DIMM) memory module. Alternatively, and in some examples, the memory module 200 may be a single in-line memory module (SIMM), a small outline dual in-line memory module (SODIMM), a registered dual in-line memory module (RDIMM), a non-volatile dual-in line memory module (NVDIMM), a micro small outline dual in-line memory module (micro-SODIMM), a high-bandwidth memory module (HBM), a compression attached memory module (CAMM), a module that is part of a solid state drive (SSD), or a module that is part of a universal flash storage (USF) device.

In some examples, and as shown in FIG. 2, a memory die 205 (e.g., the memory device 145 of FIG. 1) is one of a plurality of substantially similar memory dies populating the memory module 200. In some examples, the memory die 205 may include dynamic random access memory (DRAM) integrated circuitry, such as double data rate (DDR) DRAM integrated circuitry, graphics double data rate (GDDR) DRAM integrated circuitry, or high band width memory (HBM) that includes DRAM integrated circuitry. Alternatively, and in some examples, the memory die 205 may include system-on-chip (SoC) integrated circuitry. Alternatively, and in examples, the memory die 205 may include ferroelectric RAM (FeRAM integrated circuitry), magnetic RAM (MRAM) integrated circuitry, resistive RAM (RRAM) integrated circuitry, phase change memory (PCM) integrated circuitry, chalcogenide integrated circuitry, not-or (NOR) integrated circuitry, or not-and (NAND) integrated circuitry. Alternatively, and in some implementations, the memory die 205 may be included as part of an integrated circuit that includes multiple, stacked dies (e.g., a stack of dies including the memory die 205, another similar memory die, a logic die, and/or another suitable integrated circuit die, among other examples).

In some examples, a coating may be over, on, and/or around one or more surfaces of the memory die 205. Such a coating may environmentally and/or mechanically protect the memory die 205 and include an epoxy resin material, a polyimide material, or another suitable protective material, among other examples.

In some examples, the substrate 210 may be an organic substrate such as a PCB that includes layers of non-conductive materials (e.g., fiberglass-reinforced epoxy resin or other suitable non-conductive materials) interspersed with layers traces formed from a conductive material (e.g., copper, aluminum, gold, tin, or another suitable conductive material). Alternatively, and in some examples, the substrate 210 may be an inorganic substrate such as a ceramic substrate that includes layers of ceramic interspersed with the layers of traces formed from the conductive material.

As further shown in FIG. 2, a connection structure 215 that is one of an array of substantially similar connection structures may couple the memory die 205 and the substrate 210. In some examples, the connection structure 215 may be a controlled chip collapse connection (C4) structure formed from a conductive material (e.g., copper, gold, tin, a solderable alloy, or another suitable conductive material). Additionally, or alternatively, the connection structure 215 may be a pillar structure, a bump structure, or a solder ball structure, among other examples.

In some examples, techniques to form the substrate 210 may include forming the substrate 210 using additive (e.g., three-dimensional printing) techniques. In such examples, and as described in greater detail in connection with FIG. 3, pads and/or traces of the substrate 210 may exhibit characteristics (e.g., pitches, spacing, and/or geometric properties) that promote using the connection structure 215 to directly attach the memory die 205 to the substrate without an intervening interface (e.g., without a package substrate). In some examples, this may enable the connection structure 215 to connect with a native bond pad or a native test pad that is positioned on the memory die 205 without use of a redistribution layer (RDL).

In some examples, the connection structure 215 may be dedicated to mechanically coupling the memory die 205 with a pad and/or trace of the substrate 210. In some examples, the connection structure 215 may be dedicated to communicatively coupling the memory die 205 with the pad and/or a trace of the substrate 210. In some examples, the connection structure 215 may be dedicated to thermally coupling the memory die 205 with the pad and/or a trace of the substrate 210.

As further shown in FIG. 2, the memory module 200 may include an edge connector 220, where the edge connector 220 includes a pad 225 that is one of an array of substantially similar pads along an edge of the substrate 210. In some examples, the edge connector 220 may provide a physical connection between a memory system including the memory module 200 (e.g., the memory system 110 of FIG. 1) and a socket of a host system (e.g., a socket of the host system 105 of FIG. 1). Additionally, or alternatively, the edge connector 220 may provide an electrical interface between the memory system (e.g., integrated circuitry of the memory die 205) and the host system.

In some examples, the pad 225 includes one or more layers of conductive materials (e.g., copper, gold, aluminum, tin, or another suitable conductive material). In some examples, the pad 225 (and/or the edge connector 220) is configured for temporary, reversible connections with a socket of a system (e.g., the system 100 of FIG. 1). Configuring the pad 225 for the temporary, reversible connections may include applying a protective coating (e.g., electroless nickel immersion gold) and/or increasing a thickness of the pad 225, among other examples.

In some examples, at least portion of an interface and/or pinout provided by the edge connector 220 (e.g., locations and/or electrical functionalities associated with the array of pads including the pad 225) may conform to a JEDEC standard. As described in greater detail in connection with FIG. 3 and elsewhere herein, and in some examples, a first interface provided by the edge connector 220 may support a first data rate that is greater than a second data rate supported by a second interface between the memory die 205 and substrate 210, where the interface between the memory die 205 and the substrate 210 uses a substrate that is part of a semiconductor package and that is between the memory die 205 and the substrate 210.

FIG. 3 shows an example portion 300 of a memory module that supports memory system with direct chip attach memory die in accordance with examples as disclosed herein. The view of the portion 300 of FIG. 3 corresponds to an x-y plane and corresponds to the section A-A of the memory module 200 described in connection with FIG. 2.

As shown in FIG. 3, the substrate 210 includes a pad 305 (of an array of substantially similar pads) that is proximate a surface of the substrate 210. In some examples, the pad 305 includes one or more layers of conductive materials (e.g., copper, gold, aluminum, tin, or another suitable conductive material). In some examples, the pad 305 may be configured for a permanent connection with the connection structure 215 (e.g., via a solder joint, a compression bond, or another suitable connection that conjoins the pad 305 with the connection structure 215). Configuring the pad 305 for the permanent connection may include polishing the pad 305, cleaning the pad 305 using plasma cleaning or ultrasonic cleaning, forming an electroless nickel immersion gold surface as part of the pad 305, or applying an organic solderability preservative to a surface of the pad 305, among other examples.

As further shown in FIG. 3, the substrate 210 further includes a trace 310 (of multiple substantially similar traces) that may be routed through the substrate 210 and provide a communicative path between the pad 305 and a pad of an edge connector of the substrate 210 (e.g., the pad 225). In some examples, the trace 310 includes one or more layers of a conductive material (e.g., copper, gold, aluminum, tin, or another suitable conductive material).

In some examples, the pad 305 and/or the trace 310 may be formed using additive (e.g., three-dimensional printing) techniques. Using such techniques, the pad 305 and/or the trace 310 may be formed with sidewalls that are approximately vertical (e.g., 90°+/− approximately 1°) relative to a lateral surface of the substrate 210. The sidewalls that are approximately vertical may extend around a perimeter of the pad 305 and/or along the trace 310. Additionally, or alternatively, and using such techniques, the pad 305 and/or the trace 310 may be formed to have a width W that is included in a range of approximately 50 microns to approximately 100 microns.

As further shown in FIG. 3, and in some examples, the substrate 210 may include a solder mask 315 that extends over the sidewalls (e.g., a perimeter/edge region) of the pad 305. The solder mask 315 may include dielectric material (e.g., an epoxy resin or another suitable dielectric material) that electrically insulates and/or protects portions of the pad 305.

In some examples, and by extending over the sidewalls of the pad 305, the solder mask 315 may define an opening over the pad 305 that is used to “center” the connection structure 215 on the pad 305 during a reflow operation that conjoins the connection structure 215 with the pad 305. In such examples, the pad 305 may be referred to as a solder-mask defined (SMD) pad.

As further shown in FIG. 3, a pad 320 (of an array of substantially similar pads) is proximate a surface of the memory die 205. In some examples, the pad 320 includes one or more layers of a conductive material (e.g., copper, gold, aluminum, tin, or another suitable conductive material). Additionally, or alternatively, the pad 320 may include or more under bump metallization (UBM) layers (e.g., titanium, tungsten, nickel, titanium nitride, or another suitable UBM material) that serve as adhesion layers for the conductive layers and/or barrier layers that prevents solder diffusion into the memory die 205 during a reflow operation. In some examples, the pad 320 may be configured for a permanent connection with the connection structure 215 (e.g., via a solder joint, a bond, or another suitable connection that conjoins the pad 320 with the connection structure 215). In some examples, the pad 320 may extend along a bottom surface of the memory die 205 or there may be multiple pads 320, with buffer material 325 positioned between each pad within a pad layer in contact with the memory die 205.

In some examples, geometric properties and/or characteristics of pads and/or traces of the substrate 210 (e.g., geometric properties and/or characteristics of the pad 305 and/or the trace 310 that are resultant from additive manufacturing) may obviate usage of a redistribution layer (RDL) to locate and/or position the pad 320. In such examples, the pad 320 may be a native bond pad or a native test pad of the memory die 205. Furthermore, and in such examples, a pinout of an interface between the memory die 205 and the substrate 210 (e.g., locations and/or electrical functionalities associated with an array of pads including the pad 320 and an array of pads including the pad 305) may be specific to a design of the memory die 205, and not conform to a JEDEC standard. Such a pinout may enable a reduction in signaling lengths between the memory die 205 and the memory module 200 to reduce parasitics and improve data rates relative to another pinout associated with a substrate of a semiconductor package that may be used to encapsulate and/or house the memory die 205.

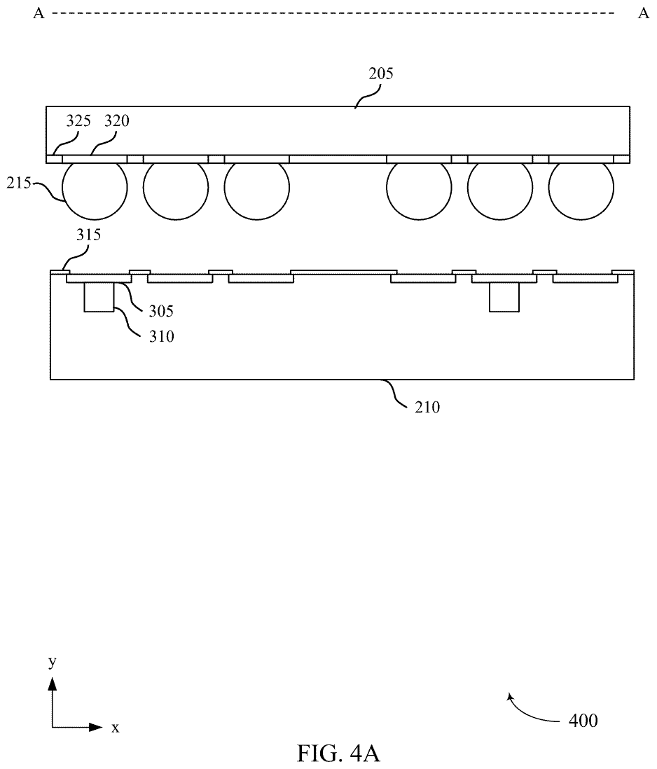

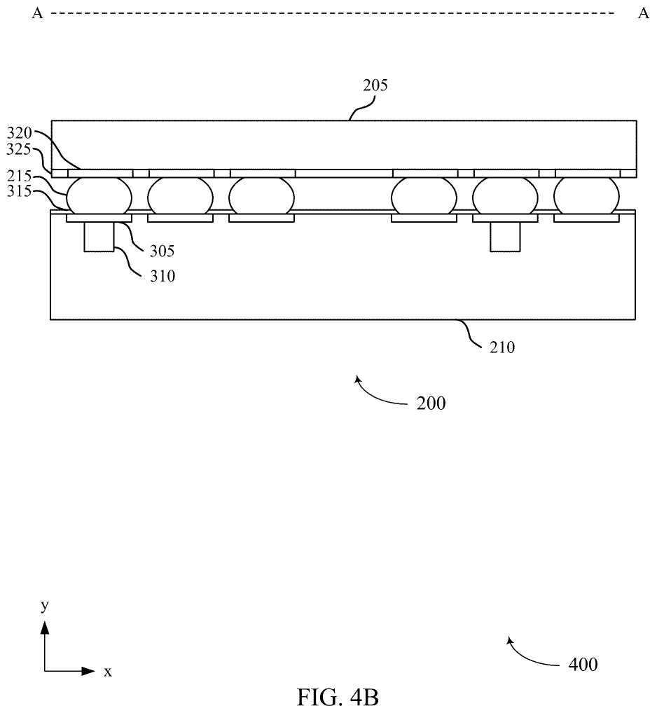

FIGS. 4A and 4B show an example manufacturing process 400 that support a memory system with a direct chip attach memory die in accordance with examples as disclosed herein. One or more operations of the manufacturing process 400 may be performed by various semiconductor manufacturing equipment at a foundry, an outsourced assembly test house (OSAT), an original equipment manufacturer (OEM), and/or a surface mount (SMT) manufacturing line. Furthermore, one or more aspects of the manufacturing process 400 may correspond to one or more aspects of a direct chip attach (DCA) process.

As shown in FIG. 4A, the manufacturing process 400 includes receiving the memory die 205. As an example, an incoming inspection tool and/or another suitable semiconductor manufacturing tool may be used as part of receiving the memory die 205. In some examples, and as further shown in FIG. 4A, the manufacturing process 400 may include receiving the memory die 205 populated with an array of connection structures (e.g., including the connection structure 215).

Alternatively, and in some examples (not shown in FIG. 4A), the manufacturing process 400 may include receiving the memory module 200 populated with the array of connection structures.

Alternatively, and in some examples (not shown in FIG. 4A), the manufacturing process 400 may include forming the array of connection structures on the memory die 205 after receipt of the memory die 205 and prior to attaching the memory die 205 to the substrate 210. In such examples, a plating tool, a bumping tool, a ball attach tool, and/or another suitable semiconductor manufacturing tool may be used as part of forming the array of connection structures.

Alternatively, and in some examples (not shown in FIG. 4A), the manufacturing process 400 may include forming the array of connection structures on the substrate 210 prior to attaching the memory die 205 to the substrate 210. In such examples, a plating tool, a bumping tool, a ball attach tool, and/or another suitable semiconductor manufacturing tool may be used as part of forming the array of connection structures.

Alternatively, and in some examples (not shown in FIG. 4A), the manufacturing process 400 may include forming the substrate 210. In such examples, a three-dimensional printing tool, a lamination tool, a plating tool, and/or another suitable semiconductor manufacturing tool may be used as part of forming the substrate 210.

As shown in FIG. 4B, the manufacturing process 400 includes attaching the memory die 205 to the substrate 210. As an example, a solder stencil tool, a pick and place tool, a compression tool, and/or a reflow tool may be used as part of attaching the memory die 205 to the substrate 210.

FIG. 4 shows a flowchart illustrating a method 400 that supports memory system with direct chip attach memory die in accordance with examples as disclosed herein. The operations of method 400 may be implemented by one or more semiconductor manufacturing tools as described herein. For example, the operations of method 400 may be performed by one or more semiconductor manufacturing tools as described with reference to FIGS. 4A and 4B.

At 405, the method may include receiving a memory die. In some examples, aspects of the operations of 405 may be performed by an incoming inspection tool.

At 410, the method may include attaching the memory die directly to a memory module printed circuit board using an array of controlled collapse chip connections, where the memory module printed circuit board includes an array of connection pads having approximately vertical sidewalls, and where a pinout of an interface formed by the array of connection pads is specific to a design of the memory die. In some examples, aspects of the operations of 410 may be performed a solder stencil tool, a pick and place tool, a compression tool, a reflow tool, and/or another suitable semiconductor manufacturing tool.

In some examples, one or more semiconductor manufacturing tools as described herein may perform a method or methods, such as the method 400. Each semiconductor manufacturing tool may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for receiving a memory die and attaching the memory die directly to a memory module printed circuit board using an array of controlled collapse chip connections, where the memory module printed circuit board includes an array of connection pads having approximately vertical sidewalls, and where a pinout of an interface formed by the array of connection pads is specific to a design of the memory die.
Aspect 2: The method, apparatus, or non-transitory computer-readable medium of aspect 1, where the memory die is populated with the array of controlled collapse chip connections.
Aspect 3: The method, apparatus, or non-transitory computer-readable medium of any of aspects 1 through 2, further including operations, features, circuitry, logic, means, or instructions, or any combination thereof for forming the array of controlled collapse chip connections on the memory die prior to attaching the memory die directly to the memory module printed circuit board.
Aspect 4: The method, apparatus, or non-transitory computer-readable medium of any of aspects 1 through 3, further including operations, features, circuitry, logic, means, or instructions, or any combination thereof for forming the array of controlled collapse chip connections on the memory module printed circuit board prior to attaching the memory die directly to the memory module printed circuit board.
Aspect 5: The method, apparatus, or non-transitory computer-readable medium of any of aspects 1 through 4, further including operations, features, circuitry, logic, means, or instructions, or any combination thereof for forming the memory module printed circuit board using an additive process that forms the array of connection pads having the approximately vertical sidewalls.
Aspect 6: The method, apparatus, or non-transitory computer-readable medium of any of aspects 1 through 5, further including operations, features, circuitry, logic, means, or instructions, or any combination thereof for attaching a second memory die to the first memory die to form a stack of memory dies that connects with the memory module printed circuit board.
Aspect 7: The method, apparatus, or non-transitory computer-readable medium of aspect 6, where the array of controlled chip collapse connections is a first array of controlled chip collapse connections and attaching the second memory die to the first memory die includes using a second array of controlled chip collapse connections to attach the second memory die to the first memory die.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 8: An apparatus, including: a printed circuit board, including: an array of first pads along an edge of the printed circuit board corresponding to a first type of interface; an array of second pads on a surface of the printed circuit board corresponding to a second type of interface that is specific to a design of the printed circuit board; and one or more conductive traces that electrically couple at least one of the first pads with at least one of the second pads, where the one or more conductive traces have approximately vertical sidewalls within the printed circuit board; and an integrated circuit, including: a semiconductor die that is directly coupled with the array of second connection pads using an array of connection structures; and a memory cell.
Aspect 9: The apparatus of aspect 8, where the approximately vertical sidewalls within the printed circuit board extend along the one or more conductive traces and around perimeters of the second pads.
Aspect 10: The apparatus of any of aspects 8 through 9, where: the first pads are configured for temporary, reversible connections with a socket, and the second pads are configured for permanent connections with the array of connection structures.
Aspect 11: The apparatus of any of aspects 8 through 10, where the array of connection structures includes controlled chip collapse connection structures.
Aspect 12: The apparatus of any of aspects 8 through 11, where the first type of interface conforms to a joint electron device engineering council standard.
Aspect 13: The apparatus of any of aspects 8 through 12, where at least one of the second pads included in the second type of interface provides a dedicated electrical coupling between the integrated circuit and the printed circuit board.
Aspect 14: The apparatus of any of aspects 8 through 13, where at least one of the second pads included in the second type of interface provides a dedicated thermal coupling between the integrated circuit and the printed circuit board.
Aspect 15: The apparatus of any of aspects 8 through 14, where at least one of the second pads included in the second type of interface provides a dedicated mechanical coupling between the integrated circuit and the printed circuit board.
Aspect 16: The apparatus of any of aspects 8 through 15, where the integrated circuit includes: a dynamic random access memory die, a NAND memory die, or a system-on-chip die.
Aspect 17: The apparatus of any of aspects 8 through 16, where the integrated circuit includes: a stack of two or more memory dies.
Aspect 18: The apparatus of any of aspects 8 through 17, where the second type of interface supports a first data rate that is greater than a second data rate supported by a third type of interface between the integrated circuit and the printed circuit board, the third type of interface uses a substrate between the integrated circuit and the printed circuit board.

An apparatus is described. The following provides an overview of aspects of the apparatus as described herein:
Aspect 19: A memory system, including: processing circuitry; and a memory module communicatively coupled with the processing circuitry, including: a substrate including an edge connector through which the memory module is communicatively coupled with the processing circuitry; and a memory die that is attached directly to the substrate using an interconnect, where the interconnect conjoins with a first connection pad on the substrate that has approximately vertical sidewalls and with a second connection pad on the memory die.
Aspect 20: The memory system of aspect 19, where the substrate is an organic substrate.
Aspect 21: The memory system of any of aspects 19 through 20, where the substrate is an inorganic substrate.
Aspect 22: The memory system of any of aspects 19 through 21, where a solder mask on a surface of the substrate extends over the approximately vertical sidewalls.
Aspect 23: The memory system of any of aspects 19 through 22, where the second connection pad has a width that is included in a range of approximately 50 microns to approximately 100 microns.
Aspect 24: The memory system of any of aspects 19 through 23, where the second connection pad is a native bond pad or a native test pad that is positioned on the memory die without use of a redistribution layer on the memory die.
Aspect 25: The memory system of any of aspects 19 through 24, where the memory module is: a single in-line memory module, a dual in-line memory module, a small outline dual in-line memory module, a registered dual in-line memory module, a non-volatile dual-in line memory module, a micro small outline dual in-line memory module, a high-bandwidth memory module, or a compression attached memory module.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a printed circuit board, comprising:
an array of first pads along an edge of the printed circuit board corresponding to a first type of interface;
an array of second pads on a surface of the printed circuit board corresponding to a second type of interface that is specific to a design of the printed circuit board; and
one or more conductive traces that electrically couple at least one of the first pads with at least one of the second pads, wherein the one or more conductive traces have approximately vertical sidewalls within the printed circuit board; and
an integrated circuit, comprising:
a semiconductor die that is directly coupled with the array of second connection pads using an array of connection structures; and
a memory cell.

2. The apparatus of claim 1, wherein the approximately vertical sidewalls within the printed circuit board extend along the one or more conductive traces and around perimeters of the second pads.

3. The apparatus of claim 1, wherein:
the first pads are configured for temporary, reversible connections with a socket, and
the second pads are configured for permanent connections with the array of connection structures.

4. The apparatus of claim 1, wherein the array of connection structures comprises controlled chip collapse connection structures.

5. The apparatus of claim 1, wherein the first type of interface conforms to a joint electron device engineering council standard.

6. The apparatus of claim 1, wherein at least one of the second pads included in the second type of interface provides a dedicated electrical coupling between the integrated circuit and the printed circuit board.

7. The apparatus of claim 1, wherein at least one of the second pads included in the second type of interface provides a dedicated thermal coupling between the integrated circuit and the printed circuit board.

8. The apparatus of claim 1, wherein at least one of the second pads included in the second type of interface provides a dedicated mechanical coupling between the integrated circuit and the printed circuit board.

9. The apparatus of claim 1, wherein the integrated circuit comprises:
a dynamic random access memory die,
a NAND memory die, or
a system-on-chip die.

10. The apparatus of claim 1, wherein the integrated circuit comprises:
a stack of two or more memory dies.

11. The apparatus of claim 1, wherein the second type of interface supports a first data rate that is greater than a second data rate supported by a third type of interface between the integrated circuit and the printed circuit board, wherein the third type of interface uses a substrate between the integrated circuit and the printed circuit board.

12. A memory system, comprising:
processing circuitry; and
a memory module communicatively coupled with the processing circuitry, comprising:
a substrate comprising an edge connector through which the memory module is communicatively coupled with the processing circuitry; and
a memory die that is attached directly to the substrate using an interconnect, wherein the interconnect conjoins with a first connection pad on the substrate that has approximately vertical sidewalls and with a second connection pad on the memory die.

13. The memory system of claim 12, wherein the substrate is an organic substrate.

14. The memory system of claim 12, wherein the substrate is an inorganic substrate.

15. The memory system of claim 12, wherein a solder mask on a surface of the substrate extends over the approximately vertical sidewalls.

16. The memory system of claim 12, wherein the second connection pad has a width that is included in a range of approximately 50 microns to approximately 100 microns.

17. The memory system of claim 12, wherein the second connection pad is a native bond pad or a native test pad that is positioned on the memory die without use of a redistribution layer on the memory die.

18. The memory system of claim 12, wherein the memory module is:
a single in-line memory module,
a dual in-line memory module,
a small outline dual in-line memory module,
a registered dual in-line memory module,
a non-volatile dual-in line memory module,
a micro small outline dual in-line memory module,
a high-bandwidth memory module, or
a compression attached memory module.

19. A method, comprising:
receiving a memory die; and
attaching the memory die directly to a memory module printed circuit board using an array of controlled collapse chip connections, wherein the memory module printed circuit board includes an array of connection pads having approximately vertical sidewalls, and wherein a pinout of an interface formed by the array of connection pads is specific to a design of the memory die.

20. The method of claim 19, wherein the memory die is populated with the array of controlled collapse chip connections.

21. The method of claim 19, further comprising:
forming the array of controlled collapse chip connections on the memory die prior to attaching the memory die directly to the memory module printed circuit board.

22. The method of claim 19, further comprising:
forming the array of controlled collapse chip connections on the memory module printed circuit board prior to attaching the memory die directly to the memory module printed circuit board.

23. The method of claim 19, further comprising:
forming the memory module printed circuit board using an additive process that forms the array of connection pads having the approximately vertical sidewalls.

24. The method of claim 19, wherein the memory die is a first memory die and further comprising:
attaching a second memory die to the first memory die to form a stack of memory dies that connects with the memory module printed circuit board.

25. The method of claim 24, wherein the array of controlled chip collapse connections is a first array of controlled chip collapse connections, and wherein attaching the second memory die to the first memory die includes using a second array of controlled chip collapse connections to attach the second memory die to the first memory die.
